(19) United States
(12) Patent Application Publication
(10) Pub. No.: US 2017/0365447 A1
(43) Pub. Date: Dec. 21, 2017

(54) PLASMA GENERATOR APPARATUS

(71) Applicant: JEHARA CORPORATION, Gyeonggi-do (KR)

(72) Inventor: Hongseub Kim, Gyeonggi-do (KR)

(21) Appl. No.: 15/487,972

(22) Filed: Apr. 14, 2017

(30) Foreign Application Priority Data
Jun. 20, 2016 (KR) 10-2016-0076416

(51) Int. Cl. H01J 37/32; C23C 16/50; C23C 16/455

(52) U.S. Cl. CPC H01J 37/32568; H01J 37/3244; C23C 16/45544; C23C 16/50; H01J 2237/332

(57) ABSTRACT

Provided is a plasma generator apparatus for forming a thin film in local plasma atmosphere at a predetermined spatial period. The plasma generator apparatus includes an electrode body part 141, a plurality of gas supply ports 142 which protrude from the electrode body part 141 at predetermined pitch intervals to direct the substrate and have nozzle holes h1 electing the reaction gas, and a plurality of purge ports 143 which are dented with steps between the gas supply ports 142 and have exhaust holes h2 exhausting the reaction gas.

### RELATED APPLICATIONS

This application claims the priority of Korean Patent Application No. 10-2016-0076416 filed on Jun. 20, 2016, in the Korean Intellectual Property Office, the disclosure of which is incorporated herein by reference.

### BACKGROUND OF THE INVENTION

### Field of the Invention

The present invention relates to a plasma generator apparatus, and a thin film deposition apparatus and an atomic layer deposition (ALD) apparatus using the plasma.

### Description of the Related Art

Recently, in order to manufacture a flexible display, an organic light-emitting diode (OLED) has received much attention, a flexible substrate has been used in manufacturing of the flexible display, and polyethylene terephthalate (PET) has been mainly used as a flexible substrate material.

For deposit on the flexible substrate, the deposition needs to be made at a low temperature to prevent damage to an organic emission layer and generally, a recommended deposition temperature is within 100° C.

Particularly, one of the most important processes of the OLED process is an encapsulation (encap) process of laminating and forming an inorganic material, an organic material, and an inorganic material so as to delay oxygen and moisture to reach the organic emission layer, and a high-quality thin film deposition at a low temperature is required.

Recently, as a method for depositing a high-quality thin film at a low temperature, an atomic layer deposition (ALD) method has been frequently researched, and the ALD method is a method of depositing atoms sequentially layer by layer in atomic units and thus, the characteristics of the deposited thin film are excellent, but there is a disadvantage in that a deposition speed is low and mass productivity is deteriorated.

Recently, in order to overcome the low deposition speed of the ALD method, a plasma enhanced atomic layer deposition (PEALD) method using plasma has been proposed.

FIG. 1A is a configuration diagram of a PEALD apparatus in the related art, and a substrate holder 20 is provided in a reaction chamber 10, and a shower head 30 for injecting gas is provided at the inner top of the reaction chamber 10. The shower head 30 is connected with an RF power generator 40 and the reaction chamber 10 and the substrate holder 20 are grounded. Reference numeral 50 represents a pumping port for exhausting the gas.

After a substrate 1 is loaded on the substrate holder 20, reaction gas and purge gas are sequentially supplied into the reaction chamber 10 through the shower head 30, and in this case, the plasma is formed between the shower head 30 and the substrate 1 by applying RF voltage to the shower head 30 through the RF power generator 40 to form a thin film on the substrate 1.

FIG. 1B is a graph illustrating a process of supplying gas for laminating an A/C thin film structure in the PEALD apparatus in the related art, and the process includes a gas supply step constituted by one period of four steps in which first reaction gas A is supplied for t1, purge gas B is supplied for t2, second reaction gas C is supplied for t3, and purge gas B is supplied for t4. FIG. 1C is a cross-sectional configuration diagram illustrating the thin film structure manufactured by the process.

In the PEALD method, because the deposition of the thin film is made by sequential supply of the gases A, B, and C, a pumping speed of the gases is very important, and in the gas supply process, because the on/off of the gases are sequentially repeated, instability of the plasma occurs. Further, the thin film deposition is made by sequentially injecting a plurality of reaction gases and thus there is a problem in that a lot of deposition process time is required.

### SUMMARY OF THE INVENTION

In order to solve the above-mentioned problems, an aspect of the present invention provides a plasma generator apparatus and an atomic layer deposition apparatus having advantages of providing a stable plasma atmosphere and improving a process speed through continuous film deposition.

According to an aspect of the present invention, there is provided a plasma generator apparatus for forming a thin film in a local plasma atmosphere at a predetermined spatial period including: a electrode body part; a plurality of gas supply ports which protrude from the electrode body part at predetermined pitch intervals to face the substrate and have nozzle holes ejecting reaction gas; and a plurality of purge ports which are dented with steps between the gas supply ports and have exhaust holes exhausting reaction byproducts.

Preferably, two kinds or more of reaction gases and purge gases may be supplied at a predetermined spatial period to correspond to the plurality of gas supply ports, respectively.

Preferably, a distance d1 (cm) between the electrode body part and the substrate and process pressure p (Torr) may be 0<p·d1≦300 Torr-cm, and more preferably, a range of the process pressure p (Torr) may be 0<p≦1000 Torr.

Preferably, a depth d2−d1 of the purge port with respect to the electrode body part may be 10 times greater than the distance d1 between the electrode body part and the substrate.

According to another aspect of the present invention, there is provided an atomic layer deposition apparatus including: a reaction chamber; a transfer unit for transferring horizontally a substrate in the reaction chamber; and a plasma generating unit for supplying reaction gas to the top of the substrate in a local plasma atmosphere at a predetermined spatial period on the substrate transferred by the transfer unit.

According to the exemplary embodiment of the present invention, in the plasma generator apparatus, the thin-film deposition is possible by injecting reaction gas and purge gas to the substrate in a local plasma atmosphere at a predetermined spatial period. Accordingly, the injection of different reaction gases is sequentially turned on/off, and as a result, the deposition may be made in a stable plasma state without the need of the injection. Particularly, in the local plasma atmosphere, while the plurality of reaction gases are injected with the purge gas, the thin-film deposition is possible, and as a result, as compared with a PEALD method in the related art, a deposition speed can be significantly increased.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A is a configuration diagram of a PEALD apparatus in the related art;

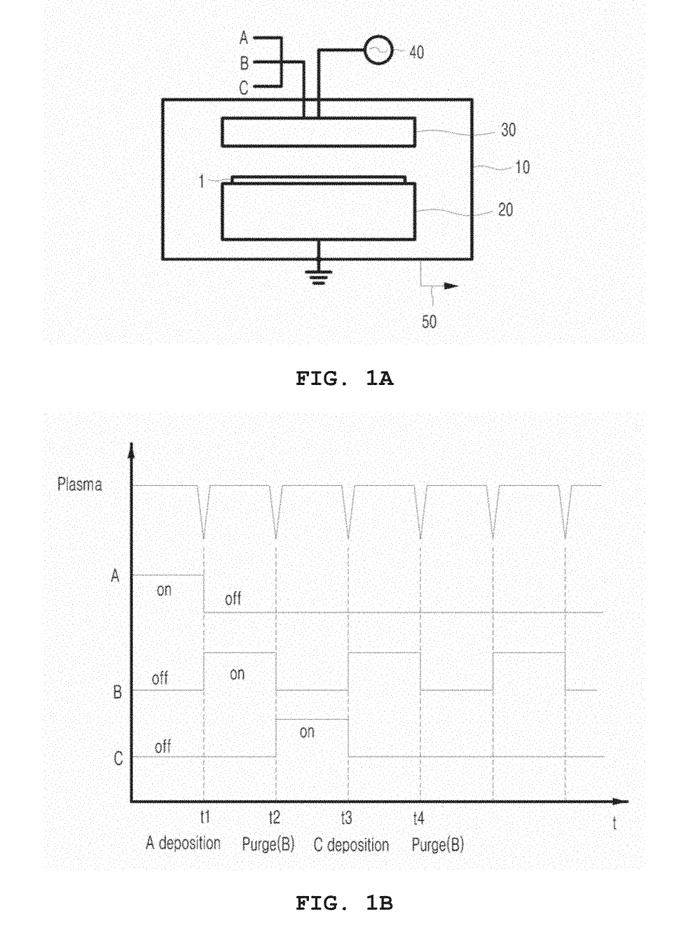

FIGS. 1B and 1C are graphs illustrating a process of supplying gas and a cross-sectional configuration diagram of a manufactured thin film structure in the PEALD apparatus in the related art, respectively;

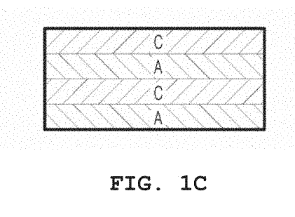

FIG. 2 is a configuration diagram of an atomic layer deposition (ALD) apparatus according to an exemplary embodiment of the present invention;

FIG. 3 is a graph illustrating Pashcen's curves for each reaction gas;

FIG. 4 is a cross-sectional configuration diagram of a plasma generating unit in the ALD apparatus of the present invention; and

FIG. 5 is a photograph obtained by capturing plasma generated locally in the plasma generating unit in the ALD apparatus of the present invention.

### DETAILED DESCRIPTION OF THE PREFERRED EMBODIMENT

Specific structural or functional descriptions presented in exemplary embodiments of the present invention are made only for the purposes of describing the exemplary embodiments according the concept of the present invention and the exemplary embodiments according the concept of the present invention may be carried out in various forms. Further, it should not be interpreted that the exemplary embodiments are limited to the exemplary embodiments described in the present specification and it should be understood that the present invention covers all the modifications, equivalents and replacements within the idea and technical scope of the present invention.

Meanwhile, terms such as first and/or second, and the like may be used for describing various components, but the components are not limited by the terms. The terms may be used only for distinguishing one component from other components, for example, a first component may be referred to as a second component, and similarly, a second component may be referred to as a first component within the scope without departing from the claims according to the concept of the present invention.

It should be understood that, when it is described that a component is “connected to” or “accesses” another component, the component may be directly connected to or access the other component or a third component may be present therebetween. In contrast, it should be understood that, when it is described that an element is “directly connected to” or “directly contact” another element, it is understood that no element is present between the element and another element. Meanwhile, other expressions for describing the relationship of the components, that is, “between” and “directly between” or “adjacent to” and “directly adjacent to” should be similarly analyzed.

Terms used in the present specification are used only to describe specific embodiments, and are not intended to limit the present invention. Singular expressions used herein include plural expressions unless they have definitely opposite meanings in the context. In the present specification, it should be understood that the term “include” or “have” indicates that a feature, a number, a step, an operation, a component, a part or the combination thereof which are implemented, but does not exclude a possibility of presence or addition of one or more other features, numbers, steps, operations, components, parts or combinations thereof, in advance.

Hereinafter, exemplary embodiments of the present invention will be described with reference to the accompanying drawings.

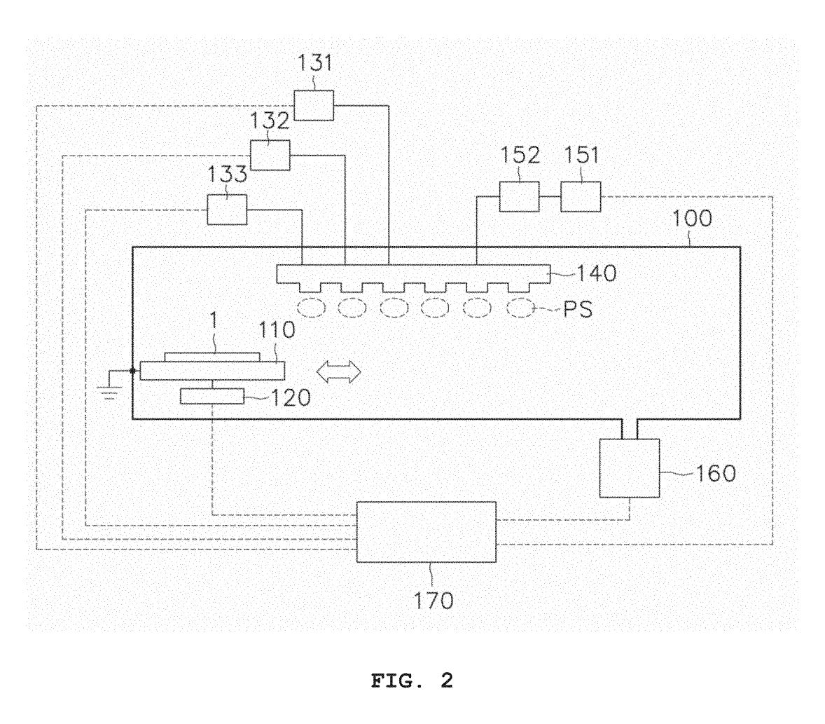

Referring to FIG. 2, an atomic layer deposition apparatus includes a reaction chamber 100 in a vacuum state, and the reaction chamber 100 includes a substrate holder 110 on which a substrate for depositing a thin film is seated, a transfer unit 120 for transferring horizontally the substrate holder 110 and a plasma generating unit 140 which is connected with a plurality gas supply units 131, 132, and 133 to inject the gas and generates local plasma (PS) with a predetermined pitch.

The plasma generating unit 140 may be connected with a power supply unit 151 for supplying RF power and an impedance matching unit 152 for optimizing and transferring the RF power, and the power supply unit may be provided by DC power.

The gas supply units 131, 132, and 133 supply a precursor of a material to be deposited on the substrate 1 or purge gas, and the precursor may be solid, liquid or gas and may be transferred as the gas when transferred to the reaction chamber 100, and in this case, carrier gas may be used. In the exemplary embodiment, the gas supply units 131, 132, and 133 may be configured by a first reaction gas supply unit 131 for supplying first reaction gas, a second reaction gas supply unit 133 for supplying second reaction gas, and a purge gas supply unit 132 for supplying purge gas.

Further, although not illustrated, the gas supply units 131, 132, and 133 and the plasma generating unit 140 may be added with well-known flow meters for controlling well-known. valves or flow rates that may control the flow of the gases.

The reaction chamber 100 may include a well-known vacuum pump 160 for maintaining the inside in a vacuum.

Reference numeral 170 represents a controller and the controller is connected with the transfer unit 120, the gas supply units 131, 132, and 133, and the vacuum pump 160 to perform a control for each driving.

Meanwhile, although not illustrated, a well-known temperature control means such as a heating lamp capable of controlling the temperature in the reaction chamber may be added, and the temperature control means may be controlled by the controller 170.

Particularly, the present invention is characterized in that the plasma generating unit generates local plasma P with a predetermined pitch interval on the substrate 1 to perform deposition of the thin film by the reaction gas.

Generally, according to a Paschen's law, among plasma generating voltage Vb, pressure p in the chamber, and a distance d between electrodes, the following Equation is established [ref. Alfred Grill, Cold Plasma in Material Fabrication, IEEE Press, 1993, P(27)].

$${V}_{b} = \frac{{C}_{2} ( p \cdot d )}{[ {C}_{2} + ln ( p \cdot d ) ]} ; \qquad [ Equation ]$$

C₁ and C₂ are constants determined by gas.

According to Equation, when a (p·d) value is too large, V_{b} is increased and thus it is difficult to maintain the plasma, and meanwhile, even when the (p·d) value is too small, V_{b} is increased and thus it is difficult to generate and maintain the plasma.

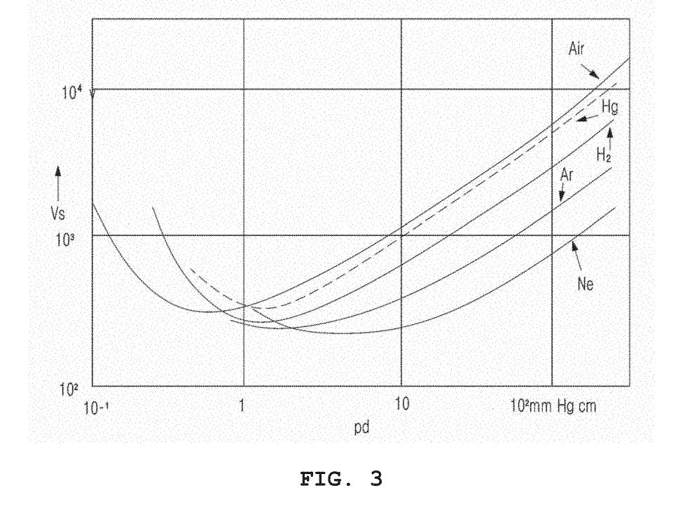

FIG. 3 is a graph illustrating Pashcen's curves for each reaction gas, and it can be seen that at approximately 1 Torr (mmHg), DC voltage at about 100 V needs to be applied to an electrode at an interval of 1 cm, and it can be seen that when the pressure is increased to 10 Torr at the same voltage, the interval for generating the plasma is 0.1 cm.

The present invention is characterized to include a plasma generating unit having a plasma generating space at a predetermined spatial period by an electrode structure constituted by a gas supply port and a purge port which have an unevenness structure at a constant pitch interval by using the Pashcen's law.

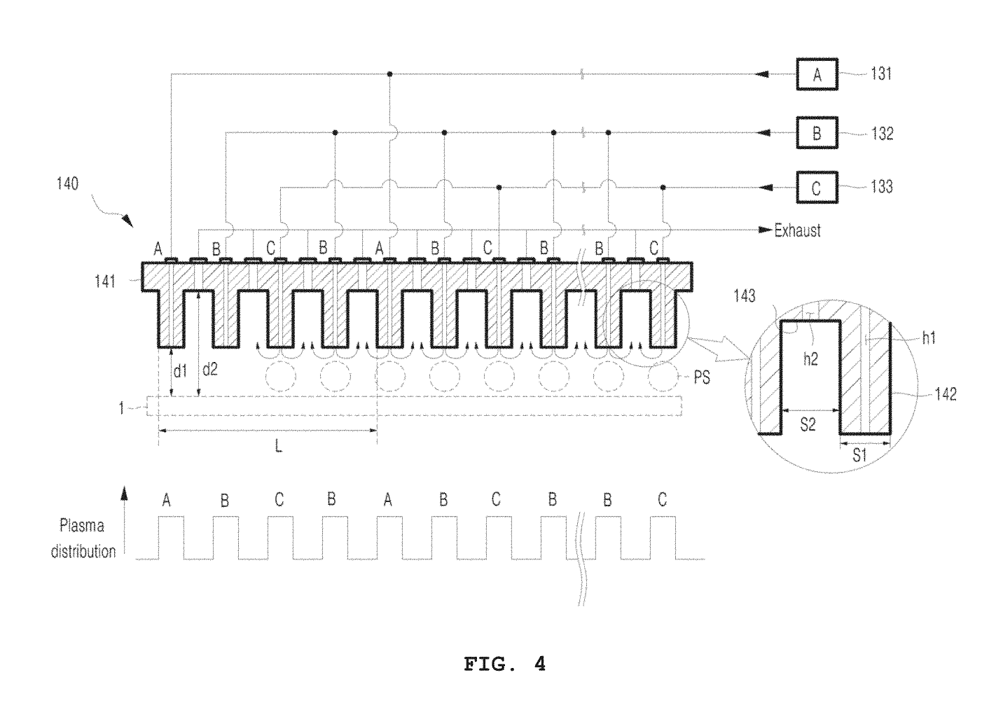

FIG. 4 is a cross-sectional configuration diagram of the plasma generating unit in the ALD apparatus of the present invention.

Specifically referring to FIG. 4, the plasma generating unit 140 includes an electrode body part 141, a plurality of gas supply ports 142 which protrude from the electrode body part 141 at predetermined pitch intervals to direct the substrate and have nozzle holes h1 which elect the reaction gas, and a plurality of purge ports 143 which are dented with steps in the gas supply port 142 and have exhaust holes h2 which exhaust the reaction gas.

The electrode body part 141 is connected with the power supply unit to supply the power and has a plurality of gas supply ports 142 and purge ports 143 which are formed on one surface facing the substrate 1 at predetermined pitch intervals.

The gas supply port 142 has a predetermined width S1, and is formed to protrude from the electrode body part 141 and formed so that the nozzle hole h1 which ejects the reaction gas pass through the electrode body part 141 and in this case, a predetermined distance d1 is provided between the electrode body part 141 and the substrate 1.

The purge port 143 is dented with a predetermined width S2 between the gas supply ports 142 and has an exhaust hole h2 which exhausts the reaction gas, and in this case, a predetermined distance d2>d1 is provided between the purge port 143 and the substrate 1. The exhaust hole h2 of the purge port 143 may be connected with an external vacuum pump and exhausts reaction byproducts and the like in the reaction chamber 100 through the purge port 143.

Preferably, at an Ar gas atmosphere, when the pressure in the reaction chamber is about 10 Torr, the distance between the electrode body part 141 and the substrate 1 is 0.1 mm<d1<100 mm and a distance d2 between the purge port 143 and the substrate 1 is equal to or greater than 100 mm, and in this case, the voltage applied to the electrode body part 141 is 1000 V or less.

That is, a depth d2<d1 of the purge port 143 with respect to the electrode body part 141 may be 10 times greater than the distance d1 between the electrode body part 141 and the substrate 1.

Preferably, in the present invention, the distance d1 (cm) between the electrode body part 141 and the substrate 1 and process pressure p (Torr) are 0<p·d1≦300 Torr-cm, and more preferably, the range of the process pressure p (Torr) is 0<p≦1000 Torr.

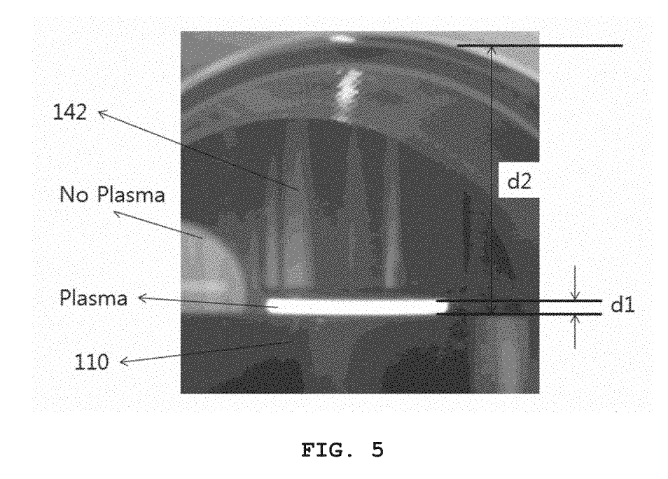

Under such a condition, in the gas supply port 142, the plasma PS is locally generated, while in the purge port 143, the plasma is not generated. Accordingly, spatially periodic plasma may be generated on the substrate 1 at a predetermined pitch interval. FIG. 5 is a photograph obtained by capturing the plasma generated locally in the plasma generating unit in the ALD apparatus of the present invention.

Meanwhile, each gas supply port 142 is connected with the gas supply units 131, 132, and 133 to supply the reaction gas and the purge gas, and in the exemplary embodiment, the first reaction gas supply unit 131 supplying the first reaction gas A, the second reaction gas supply unit 133 supplying the second react on gas B, and the purge gas supply unit 132 supplying the purge gas B are exemplified.

In the following description, when the gas supply units need to be divided according to a type of gas supplied to each gas supply port 142, the gas supply units are written with ‘A’, ‘B’, and ‘C’ at the ends of the reference numerals and referred to as ‘a first reaction gas supply unit 142A’, ‘a purge gas supply port 142B’ and ‘a second reaction gas supply port 143C’.

In the plasma generating unit 140, the first reaction gas supply unit 142A, the purge gas supply port 142B, the second reaction gas supply port 143C, and the purge gas supply port 142B sequentially disposed from the gas supply port positioned at the leftmost side of the electrode body part 141 is configured as one unit module having a predetermined length L and the unit modules may be repeatedly configured.

In the plasma generating unit 140 configured as such, when the substrate 1 is transferred at a predetermined speed in the horizontal direction in the state where the power is supplied from the power supply unit and the first reaction gas A, the purge gas B, and the second reaction gas C are supplied through the gas supply ports 142A, 142b, and 142C, respectively, the deposition is made on the top of the substrate 1 by the corresponding reaction gas and the purge gas sequentially while passing through the respective gas supply ports 142A, 142b, and 142C, and as a result, an AC thin film structure may be acquired.

For example, as an example of thin-film deposition, in the case of Al₂O₃ thin-film deposition generally adopting an encapsulation material during a solar cell manufacturing process or an OLED manufacturing process, the first reaction gas A may be trimethylaluminum (TMA) gas and the second reaction gas C may be N₂O gas or O₂ gas. As the purge gas B, inert gas such as Ar or He may be used.

Meanwhile, as another example, the plasma generating unit 140 periodically reciprocates on the substrate 1 at a distance corresponding to a length L of one period (A-B-C) of the deposition, and as a result, the AC thin film structure may be similarly acquired.

The aforementioned present invention is not limited to the aforementioned exemplary embodiments and the accompanying drawings, and it will be obvious to those skilled in the technical field to which the present invention pertains that various substitutions, modifications, and changes may be made within the scope without departing from the technical spirit of the present invention.

What is claimed is:

1. A plasma generator apparatus for forming a thin film in a local plasma atmosphere at a predetermined spatial period, the plasma generator apparatus comprising:
a electrode body part;
a plurality of gas supply ports which protrude from the electrode body part at predetermined pitch intervals to face the substrate and have nozzle holes electing reaction gas; and
a plurality of purge ports which are dented with steps between the gas supply ports and have exhaust holes exhausting reaction byproducts.

2. The plasma generator apparatus of claim 1, wherein two kinds or more of reaction gases and purge gases are supplied at a predetermined spatial period to correspond to the plurality of gas supply ports, respectively.

3. The plasma generator apparatus of claim 1, wherein a distance d1 (cm) between the electrode body part and the substrate and process pressure p (Torr) are 0<p·d1≦300 Torr-cm.

4. The plasma generator apparatus of claim 3, wherein a range of the process pressure p (Torr) is 0<p≦1000 Torr.

5. The plasma generator apparatus of claim 1, wherein a depth d2−d1 of the purge port with respect to the electrode body part is 10 times greater than the distance d1 between the electrode body part and the substrate.

6. An atomic layer deposition apparatus, comprising:
a reaction chamber;
a transfer unit for horizontally transferring a substrate in the reaction chamber; and
a plasma generating unit for supplying reaction gas to the top of the substrate in a local plasma atmosphere at a predetermined spatial period on the substrate transferred by the transfer unit.

7. The atomic layer deposition apparatus of claim 6, wherein the plasma generating unit includes a electrode body part, a plurality of gas supply ports which protrude from the electrode body part at predetermined pitch intervals to face the substrate and have nozzle holes ejecting reaction gas, and a plurality of purge ports which are dented with steps between the gas supply ports and have exhaust holes exhausting reaction byproducts.

8. The atomic layer deposition apparatus of claim 7, wherein two kinds or more of gas supply units are connected to the plasma generating unit and supply the reaction gas at a predetermined spatial period to correspond to the plurality of gas supply ports, respectively.

9. The atomic layer deposition apparatus of claim 8, wherein a depth d2−d1 of the purge port with respect to the electrode body part is 10 times greater than the distance d1 between the electrode body part and the substrate.
